(19) United States
(12) Patent Application Publication
(10) Pub. No.: US 2005/0184622 A1
(43) Pub. Date: Aug. 25, 2005

(54) Surface acoustic wave device and frequency adjustment method of the same

(75) Inventors: Takeshi Nakao, Nagaokakyo-shi (JP); Toshimaro Yoneda, Ishikawa-ken (JP); Michio Kadota, Kyoto-shi (JP)

Correspondence Address: KEATING & BENNETT, LLP, 10400 EATON PLACE, SUITE 312, FAIRFAX, VA, 22030, US

(73) Assignee: Murata Manufacturing Co., Ltd.

(21) Appl. No.: 11/097,086

(22) Filed: Mar. 31, 2005

Related U.S. Application Data
(62) Division of application No. 10/043,204, filed on Jan. 14, 2002.

(30) Foreign Application Priority Data
Feb. 13, 2001 (JP) 2001-034984

(51) Int. Cl. H03H 9/145

(52) U.S. Cl. 310/313 D

(57) ABSTRACT

A surface acoustic wave device includes a surface acoustic wave element housed in a main body of a package. The surface acoustic wave element is electrically connected to electrode lands of the package via bonding wires, and the bonding wires are arranged so as not to pass over both of IDTs and reflectors of the surface acoustic wave device.

### BACKGROUND OF THE INVENTION

1. Field of the Invention

The present invention relates to a surface acoustic wave device for use as, for example, a resonator and a bandpass filter and more particularly, the present invention relates to a surface acoustic wave device having a construction in which a surface acoustic wave element is mounted in a package and the surface acoustic wave element is connected to the package via bonding wires and a frequency adjustment method of the surface acoustic wave device.

2. Description of the Related Art

Conventionally, surface acoustic wave devices are widely used as resonators and bandpass filters. In surface acoustic wave devices, an electrode construction of interdigital-electrode transducers (hereinafter referred to as IDTs), and reflectors, is generally formed of an electrode material such as aluminum or aluminum alloy.

In Japanese Unexamined Patent Application Publication No. 8-65092, one example of a conventional surface acoustic wave device is disclosed. The surface acoustic wave device described in this prior art is described with reference to FIG. 4.

The surface acoustic wave device 101 includes a main body 102 of a package. In the main body 102 of the package, an opening 102a is provided, and a surface acoustic wave element 103 is disposed inside the opening 102a. In order to seal the surface acoustic wave element 103, a cover material is fixed on the upper surface of the main body 102 of the package so as to close the opening 102a of the main body 102 of the package.

The surface acoustic wave element 103 includes a piezoelectric substrate 104, and IDTs 105 and 106, reflectors 107 and 108, IDTs 109 and 110, and reflectors 111 and 112 which are disposed on the piezoelectric substrate 104. That is, two longitudinally coupled resonator filters 113 and 114 are constructed such that the reflectors 107 and 108 are disposed on both sides, in the surface acoustic wave propagation direction, of an area where the IDTs 105 and 106 are provided and such that the reflectors 111 and 112 are disposed on both sides, in the surface acoustic wave propagation direction, of an area where the IDTs 109 and 110 are provided.

On the other hand, in the main body 102 of the package, electrode lands 115 to 117 and 118 to 120 are disposed next to the portion where the surface acoustic wave element 103 is housed, and the surface acoustic wave element 103 is electrically connected to the electrode lands 115 to 117 and 118 to 120 via bonding wires 121 to 126.

In this surface acoustic wave device 101, the bonding wires 121 to 126 are arranged so as not to pass over the IDTs 105, 106, 109, and 110. In this way, by disposing the bonding wires 121 to 126 so as not to pass over the IDTs 105, 106, 109, and 110, the degradation of attenuation outside the passband to be caused by inductive coupling between the IDTs 105, 106, 109, and 100 and the bonding wires 121 to 126 can be reduced.

In this surface acoustic wave device 101, since the bonding wires 121 to 126 do not pass over the IDTs 105, 106, 109, and 110 as described above, the degradation of attenuation outside the passband is decreased.

However, in the surface acoustic wave device 101, regarding the electrode of the surface acoustic wave element 103, because the metal film is formed by film formation methods such as a method in which a metal film is formed by sputtering, and unnecessary portions are removed, a method in which a resist film is formed, a metal film is formed on the resist film by sputtering, and unnecessary portions are removed together with the resist film, and others, there is a problem that the film thickness, shape, and dimensions of the electrode of the surface acoustic wave element 103 vary, and, because of such variations of the electrode of the surface acoustic wave element 103, there is a problem that resonance frequencies vary. In particular, when the electrodes of the IDTs 105 and 106, reflectors 107 and 108, IDTs 109 and 110, and reflectors 111 and 112, are made of a metal of tantalum or tungsten, having a heavier mass than aluminum, variations of the central frequency become wider. As a result, a problem occurs in that the yield is reduced.

In recent years, a surface acoustic wave device making use of a Shear Horizontal (“SH”) type surface acoustic wave is under development such that an electrode of a metal having a large mass such as Ta or W, is formed on the surface of a quartz substrate. The sound velocity of the surface acoustic wave, that is, the operational central frequency, is strongly influenced by the film thickness of the electrode. When a metal such as Ta or W, having a heavy mass is used as an electrode material, the central frequency varies very significantly as a result of even a slight variation in the film thickness of the electrode.

Therefore, the yield is reduced and it is extremely difficult to manufacture the surface acoustic wave device. Accordingly, it ultimately became necessary to perform frequency adjustment of each surface acoustic wave device.

During the manufacturing process, a surface acoustic wave device 103 is cut out from a wafer, the surface acoustic wave device 103 is mounted in a main body 102 of a package, and electrical connection is achieved by using the bonding wires 121 to 126, and, after that, frequency adjustment is attempted by physically or chemically etching the surface of the surface acoustic wave device 103 by an ion beam. However, inconsistent etching often occurs and thus, frequency adjustment could not be performed with a high degree of precision.

### SUMMARY OF THE INVENTION

In order to overcome the problems described above, preferred embodiments of the present invention provide a surface acoustic wave device having electrode lands disposed in a package and connected to a surface acoustic wave element by bonding wires, and constructed such that frequency adjustment can be performed with a high degree of precision and to provide a frequency adjustment method of the surface acoustic wave device.

A surface acoustic wave device according to a preferred embodiment of the present invention includes a surface acoustic wave element having a piezoelectric substrate, at least one interdigital-electrode transducer disposed on the piezoelectric substrate, and a reflector, a package having the surface acoustic wave element mounted therein and electrode lands electrically connected to the surface acoustic wave element, and a plurality of bonding wires electrically connecting the surface acoustic wave element to the electrode lands of the package. In the surface acoustic wave device, the bonding wires are arranged so as not to pass over the interdigital-electrode transducer and the reflector of the surface acoustic wave element.

In a surface acoustic wave device according to a preferred embodiment of the present invention, an electrode material constituting the IDT and the reflector is preferably a metal having a heavier mass than that of aluminum or an alloy containing the metal.

In a surface acoustic wave device according to a preferred embodiment of the present invention, the piezoelectric substrate is preferably a quartz substrate.

According to yet another preferred embodiment of the present invention, a communication device includes a surface acoustic wave device according to preferred embodiments of the present invention described above, wherein the surface acoustic wave device defines a bandpass filter.

In a frequency adjustment method of a surface acoustic wave device according to another preferred embodiment of the present invention, frequency adjustment is performed such that the interdigital-electrode transducer and the reflector of the surface acoustic wave element mounted in the package are etched by irradiating an energy beam from above. In a frequency adjustment method of a surface acoustic wave device of a preferred embodiment of the present invention, an ion gun is used as a device for irradiating the energy beam.

Other features, elements, steps, characteristics and advantages of the present invention will become more apparent from the following detailed description of preferred embodiments with reference to the attached drawings.

### BRIEF DESCRIPTION OF THE DRAWINGS

FIG. 1 is a top view of a preferred embodiment of a surface acoustic wave device according to the present invention;

FIG. 2 shows the frequency characteristics of attenuation and the characteristics of group delay time after the surface acoustic wave device of the preferred embodiment of FIG. 1 is adjusted by irradiating an ion beam;

FIG. 3 is a block diagram of a preferred embodiment of a communication device according to the present invention;

FIG. 4 is a top view for describing an example of conventional surface acoustic wave devices; and

FIG. 5 shows the frequency characteristics of attenuation and the characteristics of group delay time when the frequency of the conventional surface acoustic wave device is adjusted.

### DETAILED DESCRIPTION OF PREFERRED EMBODIMENTS

Hereinafter, specific preferred embodiments of the present invention are described with reference to the drawings to make the present invention clear.

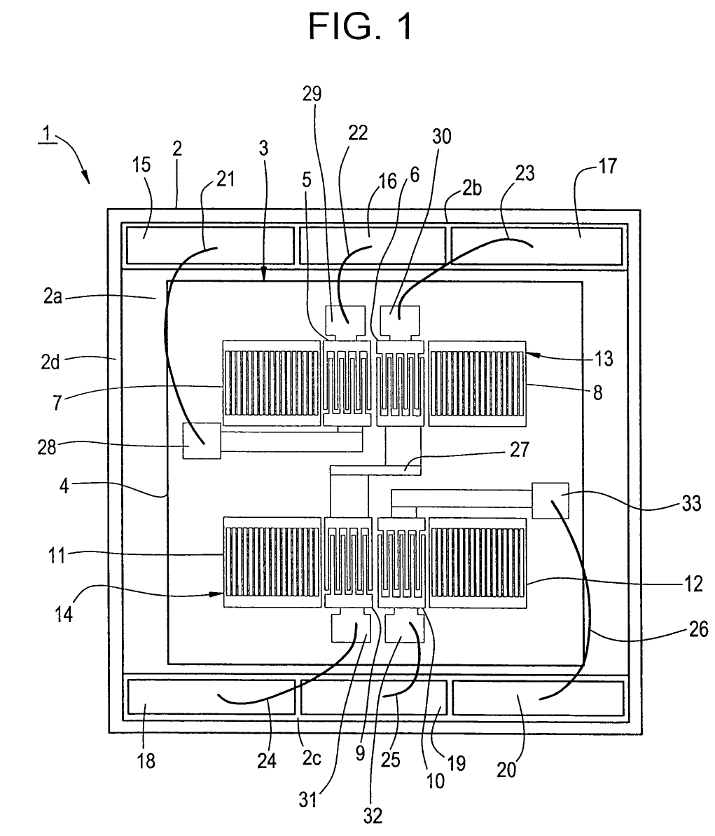

FIG. 1 is a top view showing a preferred embodiment of a surface acoustic wave device according to the present invention. In the surface acoustic wave device 1, a main body 2 of a package is preferably used. The main body 2 of the package has an opening 2a. The opening 2a preferably has a substantially rectangular shape, a step portion 2b which is higher than the bottom surface of the opening 2a is located outside of one side of the opening 2a, and a step portion 2c is located outside the other side of the opening 2a. Furthermore, the main body 2 of the package has a side wall 2d having corner portions. The side wall 2d is preferably higher than the step portions 2b and 2c, and, although not illustrated, a cover material is mounted in a fixed condition on the upper surface of the side wall 2d so as to close the opening 2a.

On the other hand, a surface acoustic wave element 3 is housed inside the opening 2a. The surface acoustic wave element 3 preferably includes piezoelectric substrate 4 which is preferably a quartz substrate in the present preferred embodiment. The piezoelectric substrate 4 preferably has a substantially rectangular plate configuration, and an electrode construction preferably made of tantalum is disposed on the top surface. In this electrode construction, IDTs 5 and 6 are disposed along the surface acoustic wave propagation direction, reflectors 7 and 8 are disposed on both sides, in the surface acoustic wave propagation direction, of an area where the IDTs 5 and 6 are provided, IDTs 9 and 10 are disposed along the surface acoustic wave propagation direction at a location separated in the direction at approximately a right angle to the surface acoustic wave propagation direction of the IDTs 5 and 6, and reflectors 11 and 12 are disposed on both sides, in the surface acoustic wave propagation direction, of the area where the IDTs 9 and 10 are provided.

A first longitudinally coupled resonator type surface acoustic wave filter 13 includes the IDTs 5 and 6 and the reflectors 7 and 8, and a second longitudinally coupled resonator type surface acoustic wave filter 14 includes the IDTs 9 and 10 and the reflectors 11 and 12. In the present preferred embodiment, the IDT 6 and IDT 9 of the first and second longitudinally coupled resonator type surface acoustic wave filters 13 and 14 are connected by a connection electrode 27 to provide a surface acoustic wave filter having a two-stage construction.

On the other hand, electrode lands 15 to 17 are disposed on the step portion 2b of the main body 2 of a package and electrode lands 18 to 20 are disposed on the step portion 2c. Although not illustrated in particular, the electrode lands 15 to 17 and 18 to 20 pass through the inside of the main body 2 of the package and extend outside the main body 2 of the package. The electrode lands 15 to 17 and 18 to 20 electrically connect the surface acoustic wave element 3 to the outside.

Pads 28 and 29 for connecting bonding wires are disposed in the IDT 5 in the first longitudinally coupled resonator type surface acoustic wave filter 13 of the surface acoustic wave element 3, and a pad 30 for connecting a bonding wire is disposed in the IDT 6. In the same way, a pad 31 for connecting a bonding wire is disposed in the IDT 9 of the second longitudinally coupled resonator type surface acoustic wave filter 14, and pads 32 and 33 for connecting bonding wires are disposed in the IDT 10. Here, the pads 28 and 33 to which bonding wires are connected are located between the first and second longitudinally coupled resonator type surface acoustic wave filter 13 and 14 and are located outside an area where the IDTs 5, 6, 9, and 10 and the reflectors 7, 8, 11, and 12 are enclosed. Then, the pads 28 to 30 and 31 to 33 of the longitudinally coupled resonator type surface acoustic wave filters 13 and 14 of the surface acoustic wave element 3 are electrically connected to the electrode lands 15 to 17 and 18 to 20 by using bonding wires 21 to 26, respectively.

As clearly understood in FIG. 1, the bonding wires 21 to 26 are arranged so as not to pass over the IDTs 5 and 6, the reflectors 7 and 8, the IDTs 9 and 10, and the reflectors 11 and 12.

When the surface acoustic wave device 1 of the present preferred embodiment is manufactured, a plurality of electrode constructions of surface acoustic wave devices 1 are formed in a matrix configuration on a wafer (not illustrated), and then, each surface acoustic wave element 3 is cut out from the wafer. Next, the surface acoustic wave element 3 is housed in the main body 2 of a package and electrical connection is performed by using the bonding wires 21 to 26. Then, when the surface acoustic wave device 1 is manufactured, the frequency characteristics of each surface acoustic wave element 3 are measured. The surface acoustic wave element 3 that is judged to be acceptable is housed in the main body 2 of a package and electrical wiring is performed by using the bonding wires 21 to 26 as described above.

Then, when the electrode is made of tantalum and the mass increases, even if variations in the electrode film thickness on the wafer are small, the frequency characteristics of the finally obtained surface acoustic wave devices 1 are likely to deviate from desired ones.

Accordingly, in the stage where the surface acoustic wave element 3 is housed in the main body 2 of a package and electrical wiring is performed by using the bonding wires 21 to 26, the frequency characteristics are measured again and, if the frequency characteristics are different from the targeted frequency, the surface acoustic wave element 3 is etched by an ion gun.

That is, an ion beam is irradiated from the top of the piezoelectric substrate 3 by using an ion gun, and the IDTs 5, 6, 9, and 10 and the reflectors 7, 8, 11, and 12 are etched to adjust the frequency. In the present preferred embodiment, since there is no bonding wire not only above the IDTs 5, 6, 9, and 10, but also above the reflectors 7, 8, 11, and 12, the above-described etching can be performed such that the ion particles irradiated by the ion gun are not disturbed by the bonding wires 21 to 26.

Therefore, frequency adjustment can be performed with a high degree of precision and very easily. This fact is described based on a specific experimental example.

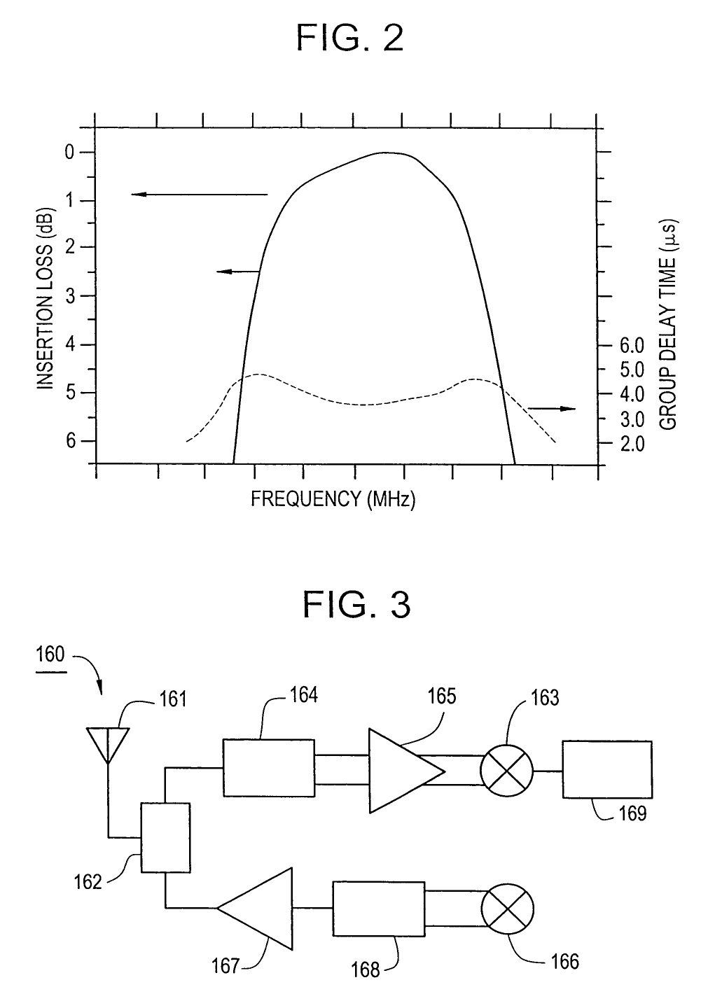

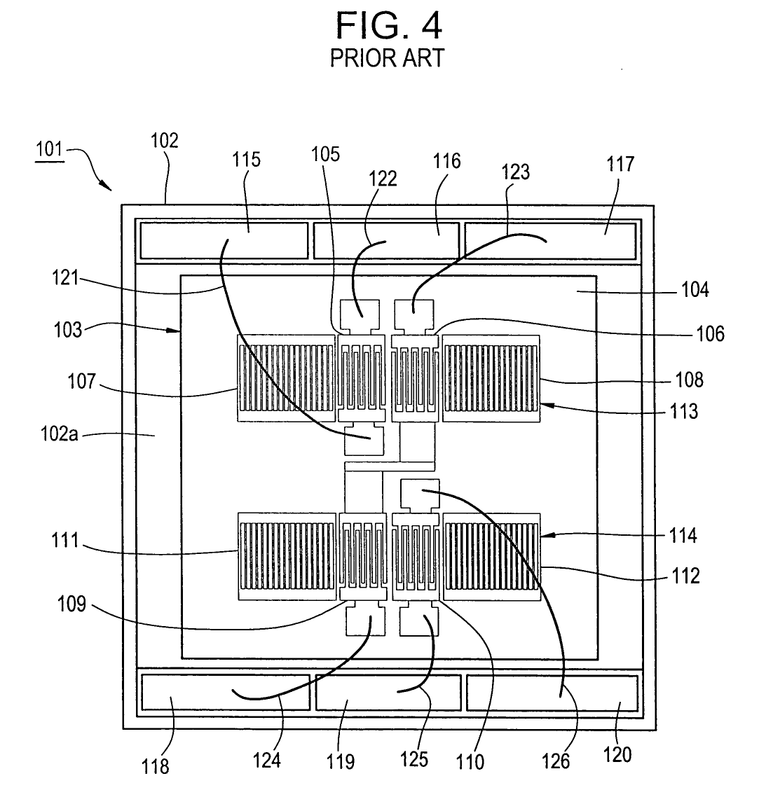

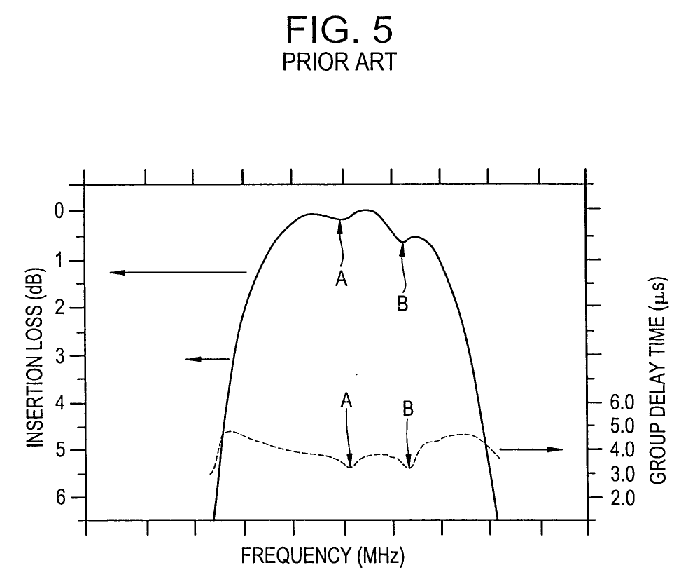

A quartz substrate having a Euler angle (0°, 127°, and 90°) was used as a piezoelectric substrate 4, and, in accordance with the above-described preferred embodiment, a surface acoustic wave device 1 making use of a SH type surface acoustic wave is produced. For comparison, a surface acoustic wave device constructed in the same way as the above-described example of preferred embodiments, except that the bonding wires 121 and 126 pass over the reflectors 107 and 112, is produced as shown in FIG. 4. Regarding these two kinds of surface acoustic wave devices, frequency adjustment was performed by irradiating an ion beam from an ion gun. The frequency characteristics of attenuation and the characteristics of group delay time of each of the thus frequency-adjusted surface acoustic wave devices are shown in FIG. 2 and FIG. 5, respectively. As shown in FIG. 5, in the surface acoustic wave device as a conventional example, the ripples shown by arrows A and B are in the bandwidth, but, in the example of preferred embodiments shown in FIG. 2, it is understood that such ripples are minimized.

That is, when the wires exist above the IDTs and the reflectors, although the area of the bonding wires, when they are looked at from the top, is small, the incident ion particles are disturbed and the uniformity of the particle density is deteriorated. Because of that, the chip surface is unevenly etched in the conventional example, and it is considered that the above-described ripples occur because of variations in the velocity of the surface acoustic wave which are caused by the uneven etching.

Moreover, in the present preferred embodiment, although tantalum is preferably used as an electrode material and a quartz substrate having the above-described specific Euler angle is used, the electrode material constituting the IDTs and the reflectors is not particularly limited in a surface acoustic wave device according to the present invention. But, in the case of an electrode in which a metal such as tantalum or alloy having a heavier mass than aluminum is used, because the effect of variations of the film thickness grows, the present invention can be preferably applied to a surface acoustic wave device in which an electrode made of a metal or ally having a heavier mass than aluminum.

As a metal having a heavier mass than that of aluminum, the metals of Au, W, Mo, Ni, Cu, Co, Cr, Zn, Fe, Mn, or other suitable material, can be used instead of tantalum. Furthermore, the electrodes in a surface acoustic wave device according to various preferred embodiments of the present invention may be constructed by using only a metal or alloy having a heavier mass than aluminum, and also the electrode may be made of a laminated construction containing these metal or alloy layers.

Furthermore, the piezoelectric substrate may be constructed by using other single quartz substrates and piezoelectric ceramic substrates except a quartz substrate.

Moreover, in the above-described preferred embodiments, an ion beam is preferably irradiated as an energy beam when etched, but other appropriate energy beams such as an electron beam instead of an ion beam may be irradiated for frequency adjustment.

Moreover, in the above-described preferred embodiments, a surface acoustic wave filter having a two-stage construction, in which first and second longitudinally coupled resonator type surface acoustic wave filters are longitudinally connected, is described, but a surface acoustic wave device according to the present invention is not limited to this, and it can be applied to ladder-type filters having a ladder-type circuit construction, appropriate surface acoustic filters of lattice-type filters in which a plurality of surface acoustic wave resonators are connected in a lattice configuration, or other surface acoustic wave devices including surface acoustic wave resonators.

Furthermore, surface acoustic waves to be utilized are not limited to a SH-type surface acoustic wave, and other surface acoustic waves such as Rayleigh waves, Love Waves, and other suitable waves, may be used.

FIG. 3 is a schematic block diagram for describing a communication device 160 including a surface acoustic wave device according to the above-described preferred embodiments of the present invention.

In FIG. 3, a duplexer 162 is connected to an antenna 161. A surface acoustic wave filter 164 and an amplifier 165 constituting an RF stage are connected between the duplexer 162 and a reception side mixer 163. Furthermore, a surface acoustic wave filter 169 in an IF stage is connected to the mixer 163. Furthermore, an amplifier 167 and a surface acoustic wave filter 168 constituting an RF stage are connected between the duplexer 162 and a transmission side mixer 166.

A surface acoustic wave device constructed in accordance with the above-described preferred embodiments of the present invention can be preferably used as a surface acoustic wave filter 169 in the communication device 160.

In a surface acoustic wave device according to preferred embodiments of the present invention, since the bonding wires are arranged such that the bonding wires do not pass over both of the IDTs and the reflectors of the surface acoustic wave element, when frequency adjustment is performed by irradiating an energy beam, the surface of the surface acoustic wave element can be etched with a high degree of precision, and, because of that, frequency adjustment can be highly accurately performed and it becomes possible to provide a surface acoustic wave device having desired filtering and resonance characteristics.

When the electrode material constituting the IDTs and the reflectors is a metal or alloy having a heavier mass than that of aluminum, the frequency is likely to greatly vary because of variations in the electrode film thickness, but, in the present invention, since frequency adjustment can be performed with a high degree of precision and with ease as described above, the present invention can be preferably utilized in a surface acoustic wave device made of a metal having a heavy mass.

When the piezoelectric substrate is made of a quartz substrate, a surface acoustic wave device making use of an SH-type wave can be constructed by constructing an electrode made of a metal or alloy having a heavier mass than aluminum on the quartz substrate, and, in that case, frequency adjustment can be easily performed in accordance with the present invention and a surface acoustic wave device having minimal variations in the frequency characteristics and making use of an SH-type surface acoustic wave can be provided.

In a frequency adjustment method of a surface acoustic wave device according to another preferred embodiment of the present invention, when the frequency of the surface acoustic wave device according to the present invention is adjusted, the frequency adjustment is performed such that the IDTs and the reflectors of the surface acoustic wave element mounted in a package are etched by irradiating an energy beam from the top, and, in this case, since there is no bonding wire above the IDTs and the reflectors, the frequency adjustment can be performed with ease and with a high degree of precision.

The IDTs and reflectors of the surface acoustic wave element can be etched by irradiating an ion beam such that an ion gun is used as a device for irradiating the above energy beam, and the frequency adjustment can be performed with a high degree of precision and with ease.

While the present invention has been particularly shown and described with reference to preferred embodiments thereof, it will be understood by those skilled in the art that the foregoing and other changes in form and details can be made without departing from the spirit and scope of the present invention.

1-12. (canceled)

13: A frequency adjustment method of a surface acoustic wave device comprising the steps of:
providing a surface acoustic wave device including a surface acoustic wave element having at least one interdigital electrode transducer and at least one reflector disposed on a piezoelectric substrate, a package having the surface acoustic wave element mounted therein and electrode lands electrically connected to the surface acoustic wave element;
arranging a plurality of bonding wires to electrically connect the surface acoustic wave element to the electrode lands of the package such that the bonding wires do not pass over the at least one interdigital electrode transducer and the at least one reflector of the surface acoustic wave element;
adjusting the frequency of the surface acoustic wave device by etching the at least one interdigital electrode transducer and the at least one reflector by irradiating an energy beam from above.

14: A frequency adjustment method of a surface acoustic wave device according to claim 13, wherein an ion gun is used in the step of irradiating the energy beam.

15: A frequency adjustment method of a surface acoustic wave device according to claim 13, wherein an electron gun is used in the step of irradiating the energy beam.
